(19) United States
(12) Patent Application Publication
(10) Pub. No.: US 2020/0003635 A1
(43) Pub. Date: Jan. 2, 2020

(54) PRESSURE SENSOR DEVICE AND METHOD FOR MANUFACTURING PRESSURE SENSOR DEVICE

(71) Applicant: TOHOKU UNIVERSITY, Sendai-shi, Miyagi (JP)

(72) Inventors: Hideki HIRANO, Sendai-shi (JP); Masanori MUROYAMA, Sendai-shi (JP); Shuji TANAKA, Sendai-shi (JP)

(73) Assignee: TOHOKU UNIVERSITY, Sendai-shi, Miyagi (JP)

(21) Appl. No.: 16/490,832

(22) PCT Filed: Jan. 23, 2018
(86) PCT No.: PCT/JP2018/001874

§ 371 Date: Sep. 3, 2019

(30) Foreign Application Priority Data
Mar. 8, 2017 (JP) 2017-043492

(51) Int. Cl. G01L 1/14; H01L 23/538; H01L 23/00

(52) U.S. Cl. CPC G01L 1/146; H01L 23/5387; H01L 2224/16221; H01L 24/16; H01L 23/5383

(57) ABSTRACT

A pressure sensor device capable of further decreasing dimensions of a pressure-sensitive element in which a semiconductor integrated circuit is integrated and increasing a spatial resolution and a method for manufacturing the pressure sensor device. A pressure sensor device includes a flexible wiring substrate and a plurality of pressure-sensitive elements in each of which a semiconductor integrated circuit is integrated. The pressure-sensitive elements are attached to one surface of the flexible wiring substrate and are electrically connected to wirings of the flexible wiring substrate. Pressure applied to the other surface of the flexible wiring substrate corresponding to an attachment position of each of the pressure-sensitive elements can be detected by a corresponding pressure-sensitive element through the flexible wiring substrate.

### FIELD OF THE INVENTION

The present invention relates to a pressure sensor device and a method for manufacturing the pressure sensor device.

### DESCRIPTION OF RELATED ART

High-sensitivity tactile sensors capable of real-time sensing need to be mounted in high density on surfaces of the body of a life support robot which is required to be coexistent with human such as a caring robot and a nursing robot in order to improve operability, safety, and communication. Moreover, for an artificial hand or an artificial leg to have the sense of touch equivalent to that of human, a tactile sensor network having high sensitivity, high density, and high time responsiviness is required similarly. Furthermore, a human interface of a next-generation smartphone or a robot arm that performs an ultra-precision assembling operation corresponding to small-volume production in great varieties equivalently requires a high-performance tactile sensor network.

Conventionally, as a technology for mounting tactile sensors in high density on a target having a complex shape such as the body, arms, hands, and fingers of a robot or an artificial hand or an artificial leg, a sensor (for example, see Patent Document 1) in which a plurality of pressure-sensitive elements are mounted on a soft flexible substrate which can be wound on a curved surface and the pressure-sensitive elements are covered with an elastic sheet member and a sensor (for example, see Patent Document 2) formed of a stacked sheet structure in which a plurality of strain gauges is allocated between two flexible sheet members and a plurality of projections is formed so as to protrude from one sheet member toward the other sheet member have been proposed. However, in such a method in which a host control unit sequentially takes out tactile information from a tactile sensor array in which pressure-sensitive elements of which the output changes according to the pressure on the flexible substrate are arranged in two-dimensionally, a sampling interval increases with increase in the number of sensors and the communication speed decreases.

Therefore, in order to solve this problem, an active-matrix-type tactile sensor array including pressure sensors arranged in a lattice form on a soft polymer film and soft organic TFT drivers corresponding to the respective sensors has been proposed to accelerate two-dimensional tactile sensing (for example, see Non-Patent Document 1). However, since an organic TFT does not have an arithmetic function for performing AD conversion, a sufficient communication speed is not achieved.

Moreover, a method in which a piezoelectric pressure sensor and an A/D converter are mounted on a flexible wiring substrate and are connected by wirings via the flexible wiring substrate has been proposed (for example, see Patent Document 3). However, noise generated by long wiring resulting from physical separation between the pressure sensor and the A/D converter is inevitable, and the data processing speed limited due to limitation in the number of wirings connecting the pressure sensor and the A/D converter. Therefore, it was difficult to construct a sensor network capable of mounting more than several hundreds of sensors and realizing real-time (time constant to milliseconds) time resolution. Furthermore, it was difficult to high-density mounting on a robot due to limited space since the sensors and the A/D converter are to be mounted simultaneously.

Therefore, in order to break the tradeoff relation between the number of sensors and the time resolution, a tactile sensor network system in which a tactile sensor and a high-functionality semiconductor integrated circuit (LSI) for high-performance data processing are integrated, the sense of touch of human such as a function of transmitting signals when a touch exceeding a threshold is obtained only (an event-driven function) or an operation of thinning out data according to adaptation is simulated to compress a data amount greatly to realize communication with fewer wirings by asynchronous bus communication has been proposed (for example, see Patent Document 4). In this system, it is possible to compress tactile signals without attenuation by integrating the semiconductor integrated circuit with the pressure sensor and to suppress wiring noise as much as possible, which may occur when the pressure sensor and the semiconductor integrated circuit are wired separately. Furthermore, it is possible to mount more than several hundreds of sensors having a time resolution of milliseconds or smaller on a robot, reduce the size of a sensor network, and easily achieve high-density mounting.

Conventionally, as a method of electrically connecting a pressure sensor in which a semiconductor integrated circuit is integrated to a flexible wiring substrate, a method (for example, see Patent Document 5) of transmitting analog pressure signals acquired by a pressure sensing unit (a portion that is displaced according to pressure and converts a displacement amount to electrical signals) of a capacitance pressure sensor in which a semiconductor integrated circuit is integrated to the semiconductor integrated circuit immediately below the pressure sensing unit to perform digital conversion and compression on the analog signals to obtain compressed signals, transmitting the compressed signals to a rear surface of the semiconductor integrated circuit through a lateral wiring of a V-groove formed side of the semiconductor integrated circuit, and outputting the signals to a flexible wiring substrate electrically connected to the rear surface of the semiconductor integrated circuit, and a method (for example, see Patent Document 6) of processing a semiconductor integrated circuit to be a thin film for a pressure sensing unit, performing digital conversion and compression directly on analog pressure signals acquired by the pressure sensing unit and taking out wirings to a flexible wiring substrate via a through-wafer wiring of a LTCC (low-temperature co-fired ceramic) substrate bonded to the semiconductor integrated circuit have been proposed.

Among these methods, according to the method which uses the through-wafer wiring, for example, as illustrated in FIG. 7, a capacitance pressure sensor 52 in which a semiconductor integrated circuit 51 is integrated has a pressure sensing unit 53 mounted on a surface of a flexible wiring substrate 54 so as to face the outer side, a through-wiring 55 provided so as to transmit signals acquired by the pressure sensing unit 53 to a surface on the opposite side of the pressure sensing unit 53, and a bonding bump 56 provided so as to electrically connect the through-wiring 55 to the flexible wiring substrate 54. The pressure sensing unit 53 is electrically connected to the semiconductor integrated circuit 51 by a plated ring bump 57. Here, the flexible wiring substrate is a substrate in which a base substrate has flexibility and a thin metal film which is an electrical wiring also has flexibility such as a bent structure (a meander structure) so that the flexible wiring substrate is mounted on a robot having a three-dimensional shape (the same hereinbelow).

### CITATION LIST

### Patent Document

Patent Document 1: Japanese Patent Application Publication No. 2007-10383

Patent Document 2: Japanese Patent Application Publication No. 2016-151531

Patent Document 3: Japanese Patent Application Publication No. 2013-178241

Patent Document 4: Japanese Patent Application Publication No. 2012-81554

Patent Document 5: Japanese Patent Application Publication No. 2013-211365

Patent Document 6: Japanese Patent Application Publication No. 2015-87131

### Non-Patent Document

Non-Patent Document 1: T. Sekitani et al., “Stretchable, Large-area Organic Electronics”, Adv. Mater., 2010, vol. 22, p. 2228-2246

### SUMMARY OF THE INVENTION

However, in the electrical connection method for the flexible wiring substrate and the pressure-sensitive element in which the semiconductor integrated circuit is integrated and the structure for realizing the method as disclosed in Patent Documents 5 and 6, a space for providing the lateral wiring in the semiconductor integrated circuit and providing the through-wiring in the LTCC substrate bonded to the semiconductor integrated circuit is required, and there is a limitation on reducing the dimensions of the pressure-sensitive element in which the semiconductor integrated circuit is integrated. Moreover, due to this, since there is a limitation in the degree of integration of the pressure-sensitive elements, it is difficult to enhance the spatial resolution.

The present invention has been made in view of the above-described problems and an object thereof is to provide a pressure sensor device capable of further decreasing dimensions of a pressure-sensitive element in which a semiconductor integrated circuit is integrated and increasing a spatial resolution and a method for manufacturing the pressure sensor device.

In order to attain the object, a pressure sensor device according to the present invention includes: a flexible wiring substrate; and a plurality of pressure-sensitive elements in each of which a semiconductor integrated circuit is integrated and which is attached to one surface of the flexible wiring substrate and is electrically connected to wirings of the flexible wiring substrate, wherein pressure applied to the other surface of the flexible wiring substrate corresponding to an attachment position of each of the pressure-sensitive elements can be detected by a corresponding pressure-sensitive element through the flexible wiring substrate.

In the pressure sensor device according to the present invention, since pressure applied to the other surface of the flexible wiring substrate is detected using the pressure-sensitive elements attached to one surface of the flexible wiring substrate via the flexible wiring substrate, it is possible to transmit signals detected on the side of the flexible wiring substrates of the pressure-sensitive elements to the wirings of the flexible wiring substrates without transmitting the same to the surface on the opposite side of the flexible wiring substrates of the pressure-sensitive elements. Therefore, the through-wiring 55 and the lateral wiring illustrated in FIG. 7 are not necessary, and it is possible to further decrease the dimensions of the pressure-sensitive element in which the semiconductor integrated circuit is integrated while eliminating a space for the through-wiring and the lateral wiring. Moreover, in this way, it is possible to mount the pressure-sensitive elements more densely and to increase the spatial resolution.

In the pressure sensor device according to the present invention, since the pressure-sensitive elements are covered by the flexible wiring substrate in relation to applied pressure, even when excessive stress is applied, it is possible to prevent damage of the pressure-sensitive elements.

In the pressure sensor device according to the present invention, in order to enhance the accuracy of detecting pressure through the flexible wiring substrate, the pressure-sensitive elements are preferably attached to the flexible wiring substrate in a state in which the pressure sensing unit of each of the pressure-sensitive elements faces the flexible wiring substrate. Moreover, the pressure-sensitive elements are preferably consisted of a parallel plate-type electrostatic capacitive sensor in which a semiconductor integrated circuit is integrated, the pressure-sensitive elements may be consisted of other pressure sensors such as a strain gauge sensor using a Piezo-resistance. When the pressure-sensitive elements are consisted of a parallel plate-type capacitance sensor, the pressure sensing unit of each of the pressure-sensitive elements is preferably formed of a diaphragm and the diaphragm is preferably attached so as to oppose one surface of the flexible wiring substrate. In such an arrangement, since the pressure applied to the pressure sensor device mainly acts on displacement of the pressure sensing unit and the substrate rigidity of the pressure-sensitive element is high, the displacement of the pressure sensing unit resulting from reaction from an attachment supporting portion of the pressure sensor device is relatively small.

In the pressure sensor device according to the present invention, the flexible wiring substrate requires not only flexibility of a base substrate and wirings for mounting on a curved surface and durability against repeated press which are conventional requirements, but also mechanical properties for minimizing pressure loss when transmitting pressure received on the other surface to one surface. That is, for example, when a displacement amount of the pressure sensing unit of each of the pressure-sensitive element in response to a contact pressure P is defined as “a”, and the thickness of a base substrate of the flexible wiring substrate is 1 and the Young's modulus is E_{f}, a displacement amount “b” of the flexible wiring substrate when the same contact pressure P is applied to the base substrate of the flexible wiring substrate is obtained by the Hooke's law.

b=P×1/E_{f} (1)

When “b” is sufficiently larger than “a”, since a larger portion of the contact pressure is consumed by deformation of the base substrate of the flexible wiring substrate, a displacement amount of the pressure sensing unit is restricted and the sensitivity becomes poor. Therefore, the displacement amount “a” of the pressure sensing unit of the pressure-sensitive element is preferably 50% or more of the displacement amount “b” of the base substrate of the flexible wiring substrate and is particularly preferably two times or more.

When the pressure sensing unit has a disc-shaped diaphragm structure, the displacement amount “a” is obtained as follows.

a=3 (1-v_{d}²)Pt⁴/8E_{d}h³ (2)

Here, t and h are the radius and the thickness of the diaphragm and E_{d} and v_{d} are the Young's modulus and the Poisson ratio of a material that forms the diaphragm, respectively. Therefore, the Young's modulus E_{f} of the base substrate of the flexible wiring substrate is preferably obtained as follows.

E_{f}>16E_{d}h³1/{3(1-v_{d}²)t⁴} (3)

On the other hand, if the base substrate of the flexible wiring substrate is too stiff, since a large portion of the applied contact pressure is consumed by bending of the flexible wiring substrate, the displacement amount of the pressure sensing unit is restricted and the sensitivity becomes also poor. When the pressure sensing unit has a disc-shaped diaphragm structure, the base substrate of the flexible wiring substrate is stiff, deformation is negligible, and bending occurs along the pressure sensing unit, the displacement amount “b” is obtained as follows.

b=3(1-v_{f}²)Pt⁴/8E_{f}1³ (4)

Here, v_{f} is the Poisson ratio of the base substrate of the flexible wiring substrate. Therefore, the Young's modulus E of the base substrate of the flexible wiring substrate is preferably obtained as follows.

E_{f}<2E_{d}(1-v_{f}²)h³/{(1-v_{d}²)L³} (5)

When the diaphragm is formed of silicon of which the radius t is 200 μm, the thickness h is 10 μm, the Young's modulus E_{d} is 130 GPa, and the Poisson ratio v_{d} is 0.18, and the base substrate of the flexible wiring substrate has a thickness 1 of 25μm and a Poisson ratio v_{f} of 0.2, the Young's modulus E_{f} of the base substrate of the flexible wiring substrate is restricted to a range of 10 MPa to 16 GPa. In this case, although a polyimide film having a Young's modulus of approximately 5 GPa and a PET film having a Young's modulus of approximately 1 GPa can be used as the base substrate of the flexible wiring substrate, a metal film is too stiff and a silicon resin film is too soft. When heat resistance and strength are taken into consideration, in the case of the above-mentioned conditions, polyimide is particularly suitable as the base substrate of the flexible wiring substrate of the pressure sensor device according to the present invention.

As described above, in the pressure sensor device according to the present invention, the Young's modulus and the thickness of the flexible wiring substrate are optimized so that a displacement amount of the pressure sensing unit of each of the pressure-sensitive element with respect to external pressure approaches a displacement amount of the flexible wiring substrate as much as possible. In this way, it is possible to transmit the external pressure to the pressure sensing unit while decreasing a pressure loss when the pressure passes through the flexible wiring substrate.

In the pressure sensor device according to the present invention, the semiconductor integrated circuit preferably can compress data output from a pressure sensing unit of each of the pressure-sensitive elements. In this case, it is possible to increase a time resolution and to achieve high-speed responsiveness even when the number of pressure-sensitive elements increases. In this way, it is possible to mount the pressure-sensitive elements in high density and in a high time resolution state. Moreover, with the compression, the data output from the pressure sensing unit of each of the pressure-sensitive elements can be used without attenuation. The semiconductor integrated circuit preferably can compress data by a function of transmitting signals when a touch exceeding a threshold is obtained only (an event-driven function) or thinning data, for example.

In the pressure sensor device according to the present invention, although the flexible wiring substrate may be a single-layer wiring substrate, the flexible wiring substrate is preferably a double-side wiring substrate and a multi-layer substrate having the wirings on at least two layers so that the degree of freedom of wiring design increases. A multi-layer substrate can be manufactured using a build-up substrate technology.

In the pressure sensor device according to the present invention, a plurality of boss structures may be formed on the other surface of the flexible wiring substrate corresponding to an attachment position of each of the pressure-sensitive elements in order to efficiently detect the applied pressure and prevent destruction of the pressure-sensitive elements. The applied pressure attenuates and is not transmitted to the pressure sensing unit if the boss structures are too soft whereas the applied pressure is caught at the periphery of the pressure sensing unit and is not transmitted to the pressure sensing unit if the boss structures are too stiff. Therefore, the boss structures need to have an appropriate stiffness and an appropriate shape (structure and thickness). In order to transmit pressure efficiently, the ratio of a displacement amount of each of the boss structures when a pressure is applied to each of the boss structures to a displacement amount of a pressure sensing unit of a corresponding pressure-sensitive element is preferably 0.2 to 5 and more preferably is 0.5 to 2. Moreover, although the boss structures may have an arbitrary shape such as a cylindrical shape, a truncated cone shape, or a dome shape, a dome shape is particularly preferable since a pressure response range widens. When the dimensions of the boss structures are smaller than the dimensions of the pressure sensing unit of each of the pressure-sensitive elements, deformation of the pressure sensing unit can be secured even when the boss structures are formed of a tough material such as metal.

In the pressure sensor device according to the present invention, a plurality of boss structures may be formed so as to make contact with a pressure sensing unit of each of the pressure-sensitive elements, pass through the flexible wiring substrate, and protrude toward the other surface of the flexible wiring substrate. In this case, it is possible to transmit the pressure applied to the boss structures to the pressure sensing unit efficiently and detect the pressure.

In the pressure sensor device according to the present invention, a transfer member capable of transmitting displacement of the flexible wiring substrate resulting from pressure applied to the other surface of the flexible wiring substrate to a pressure sensing unit of each of the pressure-sensitive elements is preferably provided between the pressure sensing unit of each of the pressure-sensitive elements and one surface of the flexible wiring substrate. In this case, a pressure loss between the flexible wiring substrate and the pressure sensing unit of each of the pressure-sensitive elements can be suppressed by the transfer member.

In the pressure sensor device according to the present invention, a filling material formed of a resin having a Young's modulus of 100 MPa or smaller (preferably 100 MPa or smaller) may be provided in a gap between one surface of the flexible wiring substrate and portions other than the pressure sensing unit of each of the pressure-sensitive element. In this case, with the filling material, it is possible to improve adhesion force between the flexible wiring substrate and each of the pressure-sensitive elements, prevent entrance of foreign materials, and secure reliability. Since the Young's modulus of the filling material is as small as 100 MPa or 10 MPa or smaller, the pressure applied to the flexible wiring substrate can be transmitted appropriately to the pressure sensing unit.

In the pressure sensor device according to the present invention, in order to prevent damage of the flexible wiring substrate and the pressure-sensitive elements, the other surface of the flexible wiring substrate may be covered with a protective resin sheet. The protective sheet is preferably formed of a material having a low Young's modulus such as a silicon resin. Moreover, when a boss structure is provided, a portion of the protective sheet covering an upper part of the boss structure is preferably formed to be relatively thin. In this way, since the pressure applied via the protective sheet is applied selectively to a boss structure, it is possible to detect the pressure appropriately.

A pressure sensor device manufacturing method according to the present invention includes: attaching a plurality of pressure-sensitive elements in each of which a semiconductor integrated circuit is integrated to one surface of a flexible wiring substrate so as to be electrically connected to wirings of the flexible wiring substrate so that pressure applied to the other surface of the flexible wiring substrate corresponding to an attachment position of each of the pressure-sensitive elements can be detected through the flexible wiring substrate.

According to the pressure sensor device manufacturing method of the present invention, it is possible to ideally manufacture the pressure sensor device according to the present invention. In the pressure sensor device manufacturing method according to the present invention, since it is not necessary to form a through-wiring to a lateral wiring on each of the pressure-sensitive elements in which a semiconductor integrated circuit (LSI) is integrated, it is possible to use the pressure-sensitive elements having smaller dimensions in which a space for the through-wiring or the lateral wiring is not present. Therefore, it is possible to mount the pressure-sensitive elements higher density and to manufacture the pressure sensor device having a high spatial resolution.

In the pressure sensor device manufacturing method according to the present invention, each of the pressure-sensitive elements is preferably electrically connected to the wirings of the flexible wiring substrate by a bonding method in which metal is used as an intermediate body. In this case, it is possible to realize high bonding strength at a relatively low temperature without a thermal damage on the base substrate of the flexible wiring substrate while realizing electrical connection. As a bonding method, a thermo compression boding method in which relatively soft metals such as gold or copper are compressed under heat, a transient liquid phase (TLP) bonding method in which a low-melting-point metal and a high-melting-point metal such as tin and copper are bonded at a temperature equal to or lower than the melting point of the low-melting-point metal to form an intermetallic compound with higher-melting-point to realize strong bonding, a solder bonding method which uses a low-melting-point metal as a bonding material, and an eutectic bonding method which uses an eutectic crystal formed by gold and tin or germanium and aluminum can be used.

When a step is formed in a bonding surface of the pressure-sensitive elements, a solder bonding method or a TLP bonding method in which metals to be bonded melt down is preferably used. In this case, it is possible to planarize the step with the melted metal. Moreover, when the thermo compression boding method is used, strong seal-bonding can be realized even if a step is formed on a bonding surface by cutting and planarizing the surface using a diamond bit or the like or planarizing the surface using a chemical mechanical polishing (CMP) method after tall bumps are formed by a plating method.

In the pressure sensor device manufacturing method according to the present invention, a transfer member which makes contact with one surface of the flexible wiring substrate when the pressure-sensitive elements are attached to the flexible wiring substrate is preferably attached to the pressure sensing unit of each of the pressure-sensitive elements in advance so that displacement of the flexible wiring substrate resulting from pressure applied to the other surface of the flexible wiring substrate can be transmitted to the pressure sensing unit of each of the pressure-sensitive elements. In this case, a pressure loss between the flexible wiring substrate and the pressure sensing unit of each of the pressure-sensitive element can be suppressed by the transfer member.

In the pressure sensor device manufacturing method according to the present invention, after the pressure-sensitive elements are attached to the flexible wiring substrate, a filling material (an under-fill resin) formed of a resin having a Young's modulus of 100 MPa or smaller (preferably 10 MPa or smaller) may be filled in a gap between one surface of the flexible wiring substrate and portions other than the pressure sensing unit of each of the pressure-sensitive elements. In this case, with the filling material, it is possible to improve adhesion force between the flexible wiring substrate and each of the pressure-sensitive elements, prevent entrance of foreign materials, and secure reliability. Since the Young's modulus of the filling material is as small as 100 MPa or 10 MPa or smaller, the pressure applied to the flexible wiring substrate can be transmitted appropriately to the pressure sensing unit.

Moreover, in this case, when bubbles enter the filling material and the bubbles remain in the vicinity of the pressure sensing unit, it is not possible to detect the applied pressure accurately. Therefore, in order to prevent the filling material from entering the vicinity of the pressure sensing unit, in the pressure sensor device manufacturing method according to the present invention, a partitioning frame that partitions a space between one surface of the flexible wiring substrate and the pressure-sensitive elements into a first space including the pressure sensing unit of each of the pressure-sensitive element and the other second space when the pressure-sensitive elements are attached to the flexible wiring substrate is preferably attached to each of the pressure-sensitive elements in advance, and after the pressure-sensitive elements are attached to the flexible wiring substrate, the filling material is preferably filled in the second space.

In the pressure sensor device manufacturing method according to the present invention, the pressure-sensitive elements are preferably flip-chip-mounted on the flexible wiring substrate. In this case, it is possible to mount the pressure-sensitive elements easily using a commercially available flip-chip bonder.

According to the present invention, it is possible to provide a pressure sensor device capable of further decreasing dimensions of a pressure-sensitive element in which a semiconductor integrated circuit is integrated and increasing a spatial resolution and to provide a method for manufacturing the pressure sensor device.

### BRIEF DESCRIPTION OF THE DRAWINGS

FIG. 1 is a cross-sectional view illustrating a pressure sensor device according to an embodiment of the present invention.

FIG. 2 is a cross-sectional view illustrating a modified embodiment having a boss structure, of the pressure sensor device according to the embodiment of the present invention.

FIG. 3 is a cross-sectional view illustrating a modified embodiment including a boss structure including a core material and a cover material, of the pressure sensor device according to the embodiment of the present invention.

FIGS. 4(a) and 4(b) are cross-sectional views illustrating a modified embodiment including a boss structure and a filling material and a modified embodiment further including a partitioning frame, of the pressure sensor device according to the embodiment of the present invention.

FIGS. 5(a) to 5(h) are cross-sectional views illustrating a method for manufacturing the pressure sensor device according to the embodiment of the present invention and FIG. 5(i) is a plan view in the step illustrated in FIG. 5(b).

FIG. 6 is a cross-sectional view illustrating a step of forming another boss structure from the method for manufacturing the pressure sensor device according to the embodiment of the present invention.

FIG. 7 is a cross-sectional view illustrating a method of electrically connecting a conventional capacitance pressure sensor in which a semiconductor integrated circuit is integrated to a flexible wiring substrate using a through-wiring.

### DETAILED DESCRIPTION OF THE INVENTION

Hereinafter, an embodiment of the present invention will be described with reference to the drawings.

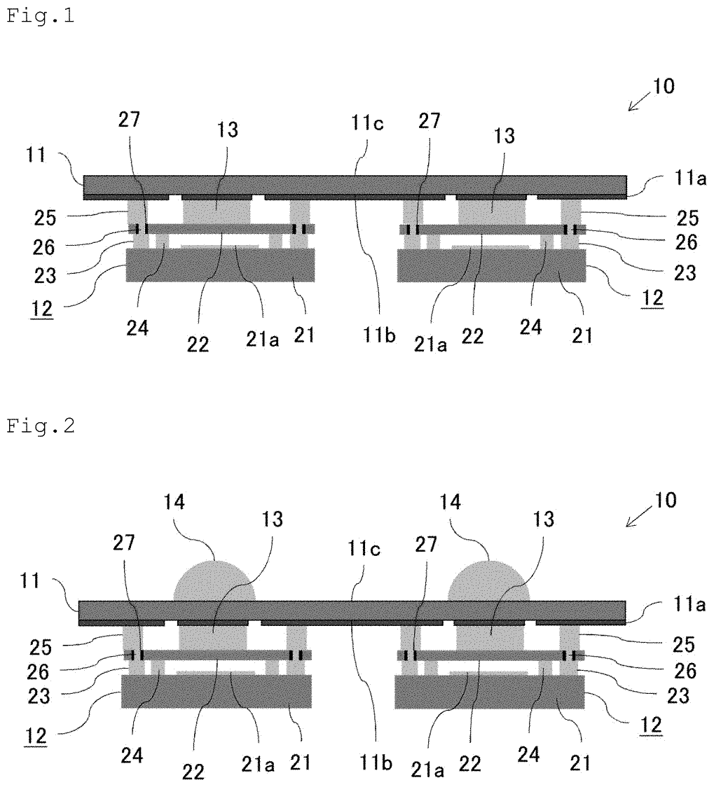

FIGS. 1 to 6 illustrate a pressure sensor device according to an embodiment of the present invention and a method for manufacturing the pressure sensor device.

As illustrated in FIG. 1, a pressure sensor device 10 includes a flexible wiring substrate 11, a plurality of pressure-sensitive elements 12, and a transfer member 13.

The flexible wiring substrate 11 is configured such that a base substrate is formed of a polyimide film and wirings 11a formed of a metal layer are formed on a surface thereof. In the flexible wiring substrate 11, the base substrate has flexibility and the metal layer that forms the wirings 11 a also has flexibility.

A semiconductor integrated circuit (LSI) 21 is integrated in each of the pressure-sensitive elements 12, and the pressure-sensitive element 12 is formed of a parallel plate-type capacitance sensor including an electrode 21a formed on a surface of the semiconductor integrated circuit 21 and a pressure sensing unit 22 formed of a diaphragm. The semiconductor integrated circuit 21 is configured to be able to compress data output from the pressure sensing unit 22 of each of the pressure-sensitive elements 12. The semiconductor integrated circuit 21 is electrically connected to a peripheral portion of the pressure sensing unit 22 by plated bumps 23. The semiconductor integrated circuit 21 can compress data by a function of transmitting signals when a touch exceeding a threshold is obtained only (an event-driven function) or thinning data, for example.

Moreover, each of the pressure-sensitive elements 12 surrounds the pressure sensing unit 22 on the inner side of the plated bumps 23 and has a ring bump 24 provided so as to mechanically and electrically connect the semiconductor integrated circuit 21 and the pressure sensing unit 22. The ring bump 24 surrounds the pressure sensing unit 22 in an air-seal manner together with the semiconductor integrated circuit 21. Each of the pressure-sensitive elements 12 is configured to transmit change in electrical capacitance resulting from deformation of the diaphragm of the pressure sensing unit 22 to the semiconductor integrated circuit 21 via the ring bump 24.

Moreover, each of the pressure-sensitive elements 12 includes an embedded electrode 26 that passes through the pressure sensing unit 22 and a silicon oxide film 27 provided between the pressure sensing unit 22 and the embedded electrode 26 at a connection position of the pressure sensing unit 22 and the plated bumps 23. The embedded electrode 26 is electrically connected to the plated bump 23. The silicon oxide film 27 is provided so as to electrically isolate the pressure sensing unit 22 and the embedded electrode 26.

Each of the pressure-sensitive elements 12 is attached to one surface 11b of the flexible wiring substrate 11 in a state in which the pressure sensing unit 22 faces the flexible wiring substrate 11 so that the diaphragm of the pressure sensing unit 22 opposes one surface 11b of the flexible wiring substrate 11. Each of the pressure-sensitive elements 12 is attached to the flexible wiring substrate 11 by bonding bumps 25 of metal-metal bonding at the position of the embedded electrode 26. In each of the pressure-sensitive elements 12, the semiconductor integrated circuit 21 is electrically connected to wirings 11a of the flexible wiring substrate 11 by the plated bump 23, the embedded electrode 26, and the bonding bump 25. The plated bump 23 and the bonding bump 25 are electrically isolated from the pressure sensing unit 22 by a silicon oxide film (not illustrated) formed on a surface of the pressure sensing unit 22. The pressure-sensitive elements 12 are not limited to a parallel plate-type electrostatic capacitance sensor but may be formed of other pressure sensors such as a strain gauge sensor which uses a Piezo-resistance.

The transfer member 13 is formed of gold and is provided between the pressure sensing unit 22 of each of the pressure-sensitive elements 12 and one surface 11b of the flexible wiring substrate 11 so as to make contact therewith. The pressure sensor device 10 is configured to be able to detect pressure applied to the other surface 11c of the flexible wiring substrate 11 corresponding to an attachment position of each of the pressure-sensitive element 12 using the corresponding pressure-sensitive element 12 with aid of the flexible wiring substrate 11 and the transfer member 13. The pressure sensor device 10 is configured such that a displacement amount of the pressure sensing unit 22 of the pressure-sensitive element 12 is equal to or larger than approximately 50%, for example, of a displacement amount of the base substrate of the flexible wiring substrate 11

Next, an operation will be described.

In the pressure sensor device 10, since pressure applied to the other surface 11c of the flexible wiring substrate 11 is detected using the pressure-sensitive elements 12 attached to one surface 11b of the flexible wiring substrate 11 via the flexible wiring substrate 11 and the transfer member 13, it is possible to transmit signals detected on the side of the flexible wiring substrates 11 of the pressure-sensitive elements 12 to the wirings 11a of the flexible wiring substrates 11 without transmitting the same to the surface on the opposite side of the flexible wiring substrates 11 of the pressure-sensitive elements 12. That is, the pressure sensor device 10 includes the flexible wiring substrate 11, the pressure sensing unit 22, and the semiconductor integrated circuit 21 stacked in that order from the side to which pressure is applied. The pressure sensor device 10 is configured to be able to transmit data output from the pressure sensing unit 22 to the semiconductor integrated circuit 21 via the ring bump 24 and transmit data compressed by the semiconductor integrated circuit 21 to the plated bump 23, the embedded electrode 26, the bonding bump 25, and the flexible wiring substrate 11 in that order.

In contrast, a conventional pressure sensor device having such through-wirings as illustrated in FIG. 7 includes a pressure sensing unit 53, a semiconductor integrated circuit 51, and a flexible wiring substrate 54 stacked in that order from the side to which pressure is applied and is configured to transmit data output from the pressure sensing unit 53 to the semiconductor integrated circuit 51 via a plated ring bump 57 and transmit data compressed by the semiconductor integrated circuit 51 to a penetration electrode 55, a bonding bump 56, and the flexible wiring substrate 54 in that order. In this manner, in the conventional pressure sensor device, an installation space for providing a penetration electrode having a high aspect ratio on a thick semiconductor integrated circuit substrate is required. In contrast, in the pressure sensor device 10, it is sufficient to form the short embedded electrode 26 on the thin pressure sensing unit 22, a long through-wiring or a long lateral wiring are not necessary, and a special space for the through-wiring or the lateral wiring is not necessary. Therefore, it is possible to further decrease the dimensions of the pressure-sensitive element 12 in which the semiconductor integrated circuit 21 is integrated. Moreover, in this way, it is possible to mount the pressure-sensitive elements 12 higher density and to enhance a spatial resolution.

In the pressure sensor device 10, since the pressure-sensitive elements 12 are covered by the flexible wiring substrate 11 in relation to applied pressure, even when excessive stress is applied, it is possible to prevent damage of the pressure-sensitive elements 12. Moreover, the pressure sensor device 10 is configured so that a displacement amount of the pressure sensing unit 22 of the pressure-sensitive element 12 is equal to or larger than approximately 50% of a displacement amount of the base substrate of the flexible wiring substrate 11 by the pressure applied to the other surface 11c. Therefore, it is possible to decrease a pressure loss when external pressure passes through the flexible wiring substrate 11 and the transfer member 13.

In the pressure sensor device 10, since the data output from the pressure sensing unit 22 of each of the pressure-sensitive elements 12 is compressed by the semiconductor integrated circuit 21, it is possible to increase a time resolution and to achieve high-speed responsiveness even when the number of pressure-sensitive elements 12 increases. In this way, it is possible to mount the pressure-sensitive elements 12 in high density and in a high time resolution state. Moreover, with the compression, the data output from the pressure sensing unit 22 of each of the pressure-sensitive elements 12 can be used without attenuation.

Moreover, in the pressure sensor device 10, since the pressure sensing unit 22 is surrounded by the ring bump 24 and the semiconductor integrated circuit 21 in an air-tight manner, it is possible to suppress performance deterioration of the pressure sensing unit 22 due to humidity and contamination. The flexible wiring substrate 11 may be a single-layer wiring substrate but may be a double-side wiring substrate and a multi-layer substrate having the wirings 11a on at least two layers so that the degree of freedom of wiring design increases.

Moreover, the pressure sensor device 10 may have a plurality of dome-shaped boss structure 14 provided on the other surface 11c of the flexible wiring substrate 11 corresponding to an attachment position of each of the pressure-sensitive elements 12. In this case, due to the boss structures 14, applied pressure can be efficiently detected and destruction of the pressure-sensitive elements 12 can be prevented. The boss structures 14 are preferably configured such that a ratio of a displacement amount of the boss structures 14 when pressure is applied to the boss structures 14 to a displacement amount of the pressure sensing unit 22 of the corresponding pressure-sensitive element 12 is 0.2 to 5 (particularly, 0.5 to 2) so that pressure is applied efficiently. Moreover, the boss structures 14 are not limited to a dome shape but may have an arbitrary shape such as a cylindrical shape or a truncated cone shape.

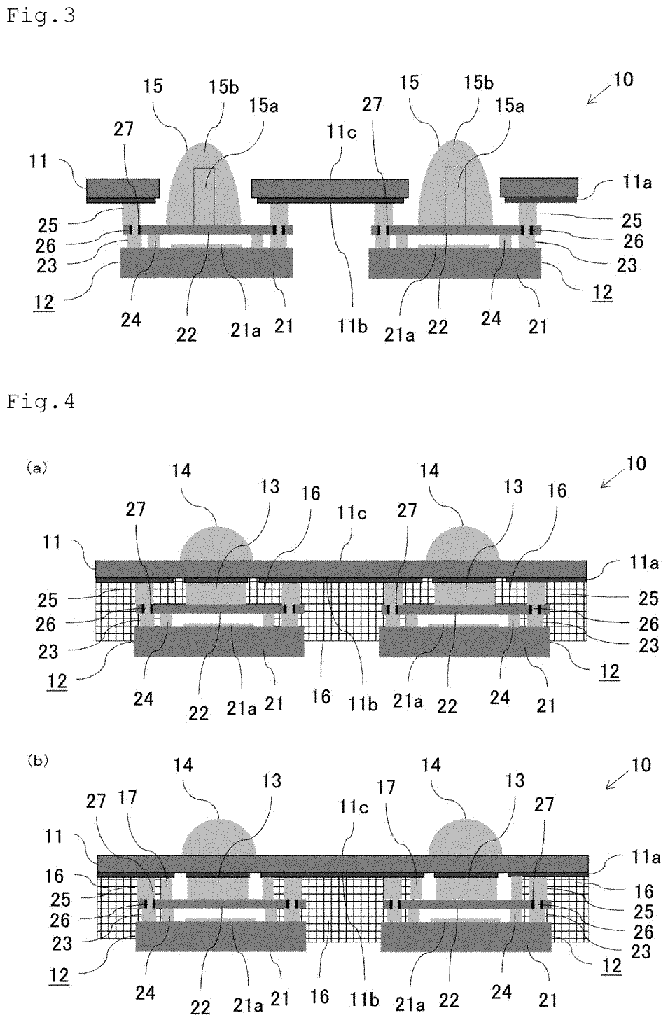

Moreover, as illustrated in FIG. 3, the pressure sensor device 10 may not have the transfer member 13 but may have a plurality of boss structure 15 that make contact with the pressure sensing units 22 of the pressure-sensitive elements 12 and pass through the flexible wiring substrate 11 so as to protrude toward the other surface 11c of the flexible wiring substrate 11. In this case, in order to enhance pressure transmission efficiency, each of the boss structures 15 preferably includes a hard core material 15a provided therein to make contact with the pressure sensing unit 22 and a soft cover material 15b that covers the circumference of the core material 15a in a dome shape. As illustrated in FIG. 3, the cover material 15b may have an outer diameter smaller than an inner diameter of a through-hole of the flexible wiring substrate 11 and may have the same outer diameter as the inner diameter of the through-hole. In this case, it is possible to transmit the pressure applied to the boss structures 15 to the pressure sensing unit 22 efficiently and detect the pressure.

Moreover, as illustrated in FIG. 4(a), the pressure sensor device 10 may have a filling material 16 formed of a resin of which the Young's modulus is 100 MPa or smaller (preferably 10 MPa or smaller) in a gap between each of the pressure-sensitive elements 12 and one surface 11b of the flexible wiring substrate 11. In this case, with the filling material 16, it is possible to improve adhesion force between the flexible wiring substrate 11 and each of the pressure-sensitive elements 12, prevent entrance of foreign materials, and secure reliability. Since the Young's modulus of the filling material 16 is as small as 100 MPa or 10 MPa or smaller, the pressure applied to the flexible wiring substrate 11 can be transmitted appropriately to the pressure sensing unit 22.

Moreover, as illustrated in FIG. 4(b), a partitioning frame 17 that surrounds the pressure sensing units 22 of the pressure-sensitive elements 12 may be provided in a space between one surface 11b of the flexible wiring substrate 11 and each of the pressure-sensitive elements 12, and the filling material 16 may be filled in a space on the outer side of the partitioning frame 17. In this case, with the partitioning frame 17, it is possible to prevent the filling material 16 from entering the vicinity of the pressure sensing unit 22. In this way, it is possible to prevent bubbles from entering the filling material 16 in the vicinity of the pressure sensing unit 22 and detect the pressure applied to the pressure sensing unit 22 accurately.

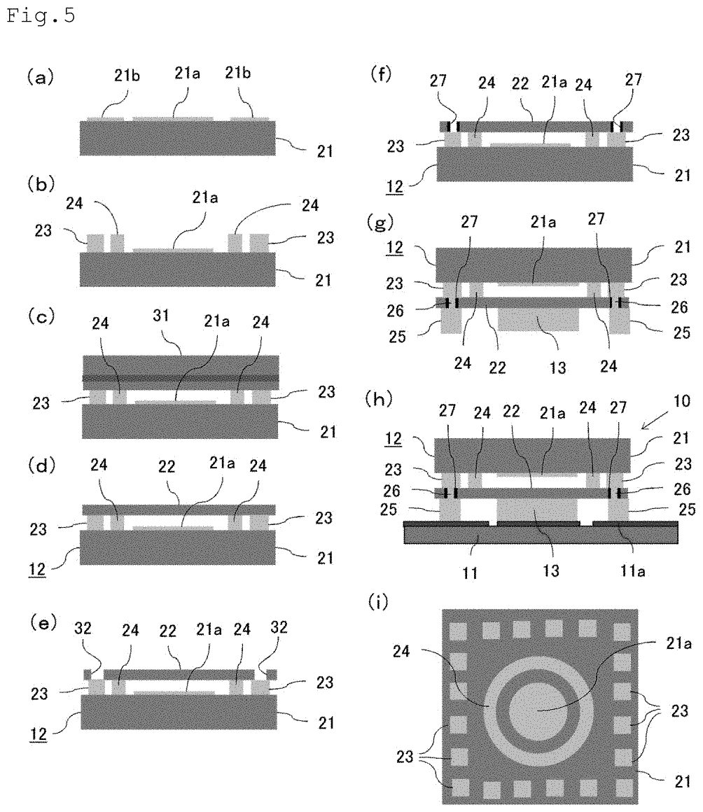

The pressure sensor device 10 is manufactured in the following manner by a pressure sensor device manufacturing method according to an embodiment of the present invention. That is, in an example illustrated in FIGS. 5(a) to 5(i), first, a pressure sensor device manufacturing method according to an embodiment of the present invention forms electrodes 21a and 21b by a sputtering method at a position and wiring pads corresponding to the pressure sensing unit 22 of the pressure-sensitive element 12, on the surface of the semiconductor integrated circuit (LSI) 21 in order to manufacture the pressure-sensitive element 12 (see FIG. 5(a)). Here, the semiconductor integrated circuit 21 is formed of an 8-inch semiconductor integrated circuit including a data compression mechanism that simulates tactile sensing system of human such as a threshold detecting operation and an adaptive operation as disclosed in Patent Document 4, for example. Subsequently, the plated bump 23 for electrical connection and the ring bump 24 for physically fixing and air-tightly sealing the pressure sensing unit 22 are formed at the position of the electrode 21b by a gold plating method. After the bumps are formed, planarization is performed using a surface planer (“DAS8920”, a product of DISCO Corporation) so that the heights of the plated bump 23 and the ring bump 24 are uniform (for example, 3 μm) (see FIGS. 5(b) and 5(i)).

A gold bonding bump pattern (for example, a thickness of 300 nm) corresponding to the pattern of the plated bump 23 of the semiconductor integrated circuit 21 is formed on a SOI substrate 31 (for example, an 8-inch size substrate including a device layer (10 μm), a BOX layer (1 μm), and a handling layer (400 μm)) by a sputtering method and an etching method separately from the semiconductor integrated circuit 21. The SOI substrate 31 and the semiconductor integrated circuit 21 are aligned so that the bump patterns correspond to each other, and the substrate 31 and the circuit 21 are bonded and integrated by a thermo compression bonding method (for example, 250° C. and 10000 N) (see FIG. 5(c)). The handling layer and the BOX layer of the SOI substrate 31 are removed completely using a dry etching method, and a disc-shaped silicon diaphragm (for example, a thickness of 10 μm and a diameter of 400 μm) is formed as the pressure sensing unit 22 (see FIG. 5(d)). In this way, the pressure-sensitive element 12 in which the semiconductor integrated circuit 21 is integrated can be manufactured.

Subsequently, a hole 32 for taking out electrodes is formed at a position corresponding to the plated bump 23 of the diaphragm by a dry etching method (see FIG. 5(e)), and a side surface of the hole 32 is covered with a silicon oxide film 27 using plasma CVD process (see FIG. 5(f)). This hole 32 has a small size and a small aspect ratio (for example, a diameter of 10 μm and a depth of 20 μm) unlike the hole for through-wirings (for example, a diameter of 100 μm and a depth of 300 μm) formed in such a conventional semiconductor integrated circuit substrate as illustrated in FIG. 7. Therefore, it is possible to easily form the hole 32 without requiring a special space. Subsequently, the embedded gold electrode 26 and the bonding bump 25 that pass through the hole 32 and extend toward an upper side of the diaphragm are formed collectively using a plating method, and planarization is performed using a surface planer so that the height of the bump on the diaphragm is uniform (for example, 3 μm) (see FIG. 5(g)). At the same time, the transfer member 13 formed of gold having a slightly smaller diameter than the diaphragm is also formed immediately above a central portion of the diaphragm and planarization is performed so that the height is uniform (for example, 3 μm) (see FIG. 5(g)).

In this way, the pressure-sensitive element 12 to which the transfer member 13 and the bonding bump 25 are attached is fragmented into small dies by dicing and is then bonded onto the flexible wiring substrate 11 using a flip-chip bonder. The flexible wiring substrate 11 is configured such that a polyimide film (for example, a thickness of 25 μm) is used as a substrate, a wiring (for example, a thickness of 300 nm) 11a formed of a gold layer is formed on a bonding portion of the surface by sputtering, and the wiring 11a and the bonding bump 25 are electrically connected (see FIG. 5(h)). In this way, the pressure sensor device 10 can be manufactured.

As described above, since the pressure sensor device manufacturing method according to the embodiment of the present invention electrically connects the pressure-sensitive elements 12 to the wiring 11a of the flexible wiring substrate 11 by a bonding method which uses metal as an intermediate body, it is possible to realize strong bonding at a relatively low temperature without a thermal damage on the base substrate of the flexible wiring substrate 11 while realizing electrical connection. Copper, silver, and the like in addition to gold may be used as metal used in thermo compression boding. A boding method is not limited to a thermo compression boding method but a TLP bonding method, a solder bonding method, and a eutectic bonding method may be used. Moreover, since the pressure sensor device manufacturing method according to the embodiment of the present invention lays wirings on the semiconductor integrated circuit 21 using metal bonding pads, it is possible to take out a number of signal wirings as compared to through-wirings and to realize faster communication.

### EXAMPLE 1

The dimensions of a conventional capacitance pressure-sensitive element in which a semiconductor integrated circuit is integrated and a penetration electrode is formed were at least 2.0 mm square, whereas the pressure-sensitive elements 12 of the pressure sensor device 10 according to the embodiment of the present invention which does not require a penetration electrode can be manufactured in dimensions of 1.0 mm square and the area can be reduced by ¼ even when the elements were manufactured using equivalent circuits and design rules. Therefore, the elements can be mounted in higher density than the conventional electrodes.

Moreover, the pressure sensor device 10 manufactured by the pressure sensor device manufacturing method according to the embodiment of the present invention could detect force of 0.01 N to 0.5 N as digital data when pressure was applied to a pressure sensing position of the flexible wiring substrate 11. Moreover, the functions of a threshold detecting operation and an adaptive operation were verified. Moreover, when the pressure sensor device 10 was wound around a body surface of a robot and was mounted using a silicon resin adhesive, the pressure sensor device 10 could be attached without any gap. Even after the pressure sensor device 10 was mounted on a robot, it was possible to detect the force (that is, the sense of touch) applied from the outside similarly.

### EXAMPLE 2

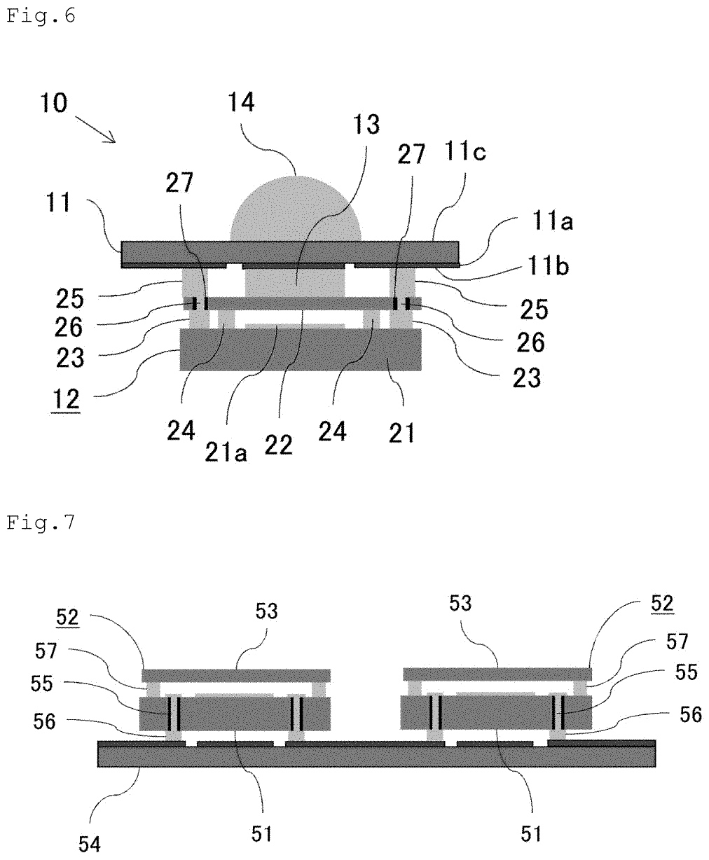

After the pressure sensor device 10 was manufactured according to FIGS. 5(a) to 5(i), as illustrated in FIG. 6, a hemispheric dome-shaped boss structure 14 formed of polyurethane (Young's modulus: 1 GPa) having a diameter of 800 μm was formed on the other surface 11c of the flexible wiring substrate 11 corresponding to an attachment position of each of the pressure-sensitive elements 12 using a dispenser. When force of 1 N was applied to the boss structure 14, a deformation amount of the boss structure 14 was 800 nm, a deformation amount of the silicon diaphragm was 1200 nm, and the ratio thereof was 1.5.

Moreover, when pressure was applied to the boss structure 14 of the pressure sensor device 10, it was possible to detect force of 0.01 N to 2 N as digital data. Moreover, the functions such as a threshold detecting operation and an adaptive operation were verified. Although destruction of the pressure sensing unit 22 was not observed until the pressure applied to the pressure sensing unit 22 reached 10 N, an irreversible data output error which suggested destruction of the pressure sensing unit 22 was observed when force exceeding 10 N was applied.

### EXAMPLE 3

After the pressure sensor device 10 was manufactured according to FIGS. 5(a) to 5(i), as illustrated in FIG. 4(b), a silicon resin was filled into the gap between one surface 11b of the flexible wiring substrate 11 and portions of each of the pressure-sensitive elements 12 other than the pressure sensing unit 22. In this case, a ring-shaped metal pad (the partitioning frame 17) was provided between the wiring pad and the pressure sensing unit 22 of the diaphragm so as to surround the diaphragm, and the filling material 16 was filled into the outer side of the metal pad so that the vicinity of the diaphragm is not filled with the filling material 16. Moreover, similarly to FIG. 6, a hemispheric dome-shaped boss structure 14 formed of polyurethane (Young's modulus: 1 GPa) having a diameter of 800 μm was formed on the other surface 11c of the flexible wiring substrate 11 corresponding to an attachment position of each of the pressure-sensitive elements 12.

When pressure was applied to the boss structure 14, it was possible to detect force of 0.01 N to 2 N as digital data. Moreover, the functions such as a threshold detecting operation and an adaptive operation were verified. Although destruction of the pressure sensing unit 22 was not observed until the pressure applied to the pressure sensing unit 22 reached 15 N, an irreversible data output error which suggested destruction of the pressure sensing unit 22 was observed when force exceeding 15 N was applied.

When the pressure sensor device 10 having the filling material 16 and the boss structure 14 was wound around a body surface of a robot and was mounted using a silicon resin adhesive, the pressure sensor device 10 could be attached without any gap. Even after the pressure sensor device 10 was mounted on a robot, it was possible to detect the force (that is, the sense of touch) applied from the outside. Particularly, a data error was observed for the device without the filling material 16 when 3000 times of bending were performed on a portion such as a joint portion which is repeatedly bent whereas a data error was not observed for the device with the filling material 16 even when 50000 times of bending were performed.

### EXAMPLE 4

After the diaphragm having a diameter of 400 μm was formed according to FIGS. 5(a) to 5(f), as illustrated in FIG. 3, a cylindrical copper pillar having a diameter of 200 μm and a height of 100 μm was formed by a plating method instead of the transfer member 13. Furthermore, a through-hole having a diameter of 300 μm was formed in the flexible wiring substrate 11 and the pressure-sensitive element 12 was bonded to the flexible wiring substrate 11 so that a copper pillar passed through the through-hole. After that, the pillar was used as the core material 15a and a hemispherical dome-shaped cover material 15b formed of polyurethane having a diameter of 800 μm covered the core material 15a to form the boss structure 15.

When pressure was applied to the boss structure 15, it was possible to detect force of 0.01 N to 2 N as digital data. Moreover, the functions such as a threshold detecting operation and an adaptive operation were verified. Although destruction of the pressure sensing unit 22 was not observed until the pressure applied to the pressure sensing unit 22 reached 20 N, an irreversible data output error which suggested destruction of the pressure sensing unit 22 was observed when force exceeding 20 N was applied.

### Comparative Example 1

A pressure sensor device similar to that of Example 2 was manufactured except that a silicon resin (Young's modulus: 2 MPa) was used as a material of the boss structure 14. Although force of 0.2 N to 2 N was detected as digital data when pressure was applied to the boss structure 14, it was not possible to detect weak force of 0.2 N or smaller. A deformation amount of the boss structure 14 was 80 μm when force of 0.1 N was applied, whereas a deformation amount of the silicon diaphragm was 0.004 μm and was a detection limit of electrostatic capacitance or smaller.

### Comparative Example 2

A pressure sensor device similar to that of Example 2 was manufactured except that a solder (Young's modulus: 80 GPa) was used as a material of the boss structure 14. When pressure was applied to the boss structure 14, it was not possible to detect force of 10 N or smaller. An estimated deformation amount of the boss structure 14 when force of 10 N was applied was 0.1 nm according to simulation based on a finite element method, whereas a deformation amount of the silicon diaphragm was 5 nm which is a detection limit of electrostatic capacitance.

### Comparative Example 3

A pressure sensor device similar to that of Example 3 was manufactured except that the filling material 16 was an epoxy resin. When pressure was applied to the boss structure 14 of the pressure sensor device, it was not possible to detect force of 0.2 N or smaller.

### REFERENCE SIGNS LIST

10: Pressure sensor device

11: Flexible wiring substrate

11a: Wiring

11b: One surface

11c: The other surface

12: Pressure-sensitive element

21: Semiconductor integrated circuit

21a, 21b: Electrode

22: Pressure sensing unit

23: Plated bump

24: Ring bump

25: Bonding bump

26: Embedded electrode

27: Silicon oxide film

13: Transfer member

14: Boss structure

15: Boss structure

15a: Core material

15b: Cover material

16: Filling material

17: Partitioning frame

31: SOI substrate

32: Hole

1. A pressure sensor device comprising:
a flexible wiring substrate; and
a plurality of pressure-sensitive elements in each of which a semiconductor integrated circuit is integrated and which is attached to one surface of the flexible wiring substrate and is electrically connected to wirings of the flexible wiring substrate, wherein pressure applied to the other surface of the flexible wiring substrate corresponding to an attachment position of each of the pressure-sensitive elements can be detected by a corresponding pressure-sensitive element through the flexible wiring substrate.

2. The pressure sensor device according to claim 1, wherein
each of the pressure-sensitive elements is formed of a parallel plate-type electrostatic capacitance sensor in which a semiconductor integrated circuit is integrated.

3. The pressure sensor device according to claim 1, wherein
the semiconductor integrated circuit can compress data output from a pressure sensing unit of each of the pressure-sensitive elements.

4. The pressure sensor device according to claim 1, wherein
the flexible wiring substrate is formed of a multi-layer substrate having wirings on at least two layers.

5. The pressure sensor device according to claim 1, wherein
a plurality of boss structure is formed on the other surface of the flexible wiring substrate corresponding to an attachment position of each of the pressure-sensitive elements.

6. The pressure sensor device according to claim 1, wherein
a plurality of boss structure is formed so as to make contact with a pressure sensing unit of each of the pressure-sensitive elements, pass through the flexible wiring substrate, and protrude toward the other surface of the flexible wiring substrate.

7. The pressure sensor device according to claim 5, wherein
a ratio of a displacement amount of each of the boss structures when a pressure is applied to each of the boss structures to a displacement amount of a pressure sensing unit of a corresponding pressure-sensitive element is 0.2 to 5.

8. The pressure sensor device according to claim 5, wherein
each of the boss structures has a dome shape.

9. The pressure sensor device according to claim 1 wherein
a transfer member capable of transmitting displacement of the flexible wiring substrate resulting from pressure applied to the other surface of the flexible wiring substrate to a pressure sensing unit of each of the pressure-sensitive elements is provided between the pressure sensing unit of each of the pressure-sensitive elements and one surface of the flexible wiring substrate.

10. The pressure sensor device according to claim 1 wherein
a filling material formed of a resin having a Young's modulus of 100 MPa or smaller is provided in a gap between one surface of the flexible wiring substrate and portions other than the pressure sensing unit of each of the pressure-sensitive element.

11. A pressure sensor device manufacturing method comprising:
attaching a plurality of pressure-sensitive elements in each of which a semiconductor integrated circuit is integrated to one surface of a flexible wiring substrate so as to be electrically connected to wirings of the flexible wiring substrate so that pressure applied to the other surface of the flexible wiring substrate corresponding to an attachment position of each of the pressure-sensitive elements can be detected via the flexible wiring substrate.

12. The pressure sensor device manufacturing method according to claim 11, wherein
each of the pressure-sensitive elements is electrically connected to the wirings of the flexible wiring substrate by a bonding method in which metal is used as an intermediate body.

13. The pressure sensor device manufacturing method according to claim 12, wherein
each of the pressure-sensitive elements is electrically connected to the wirings of the flexible wiring substrate using a thermo compression boding method or a TLP bonding method.

14. The pressure sensor device manufacturing method according to claim 11, wherein
a transfer member which makes contact with one surface of the flexible wiring substrate when the pressure-sensitive elements are attached to the flexible wiring substrate is attached to the pressure sensing unit of each of the pressure-sensitive elements in advance so that displacement of the flexible wiring substrate resulting from pressure applied to the other surface of the flexible wiring substrate can be transmitted to the pressure sensing unit of each of the pressure-sensitive elements.

15. The pressure sensor device manufacturing method according to claim 11, wherein
after the pressure-sensitive elements are attached to the flexible wiring substrate, a filling material formed of a resin having a Young's modulus of 100 MPa or smaller is filled in a gap between one surface of the flexible wiring substrate and portions other than the pressure sensing unit of each of the pressure-sensitive elements.

16. The pressure sensor device manufacturing method according to claim 15, wherein
a partitioning frame that partitions a space between one surface of the flexible wiring substrate and the pressure-sensitive elements into a first space including the pressure sensing unit of each of the pressure-sensitive element and the other second space when the pressure-sensitive elements are attached to the flexible wiring substrate is attached to each of the pressure-sensitive elements in advance, and
after the pressure-sensitive elements are attached to the flexible wiring substrate, the filling material is filled in the second space.

17. The pressure sensor device manufacturing method according to claim 11, wherein
the pressure-sensitive elements are flip-chip-mounted on the flexible wiring substrate.
